(19) United States
(12) Patent Application Publication
(10) Pub. No.: US 2009/0170315 A1
(43) Pub. Date: Jul. 2, 2009

(54) Method for Forming Tungsten Plug

(76) Inventor: Ka Moon Seok, Bupyeong-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/333,373

(22) Filed: Dec. 12, 2008

(30) Foreign Application Priority Data
Dec. 27, 2007 (KR) 10-2007-0138548

(51) Int. Cl. H01L 21/44

(52) U.S. Cl. 438/675; 257/E21.536

(57) ABSTRACT

A method for forming a tungsten plug is provided. The method can include forming a first tungsten seed layer on an insulating layer having a via hole, forming a second tungsten seed layer on the first tungsten seed layer, and forming a tungsten-buried layer in the via hole. The second tungsten seed layer can be from about 1.3 times to about 2.5 times thicker than the first tungsten seed layer.

### CROSS-REFERENCE TO RELATED APPLICATION

The present application claims the benefit under 35 U.S.C. §119 of Korean Patent Application No. 10-2007-0138548, filed Dec. 27, 2007, which is hereby incorporated by reference in its entirety.

### BACKGROUND

As semiconductor devices become more integrated, contact holes and via holes for connection wires of integrated circuits continue to become smaller.

Accordingly, filling a metal material in the contact holes and the via holes has become an important process during the fabrication of a semiconductor device.

A tungsten (W) plug process is often used for a contact and via process. Tungsten is generally used as an important material of a connection line since it has a temperature expansion coefficient similar to that of silicon (Si). Additionally, W has a superior step coverage property, low resistance, and the ability to help inhibit electron detachment due to a high melting point metal characteristic.

In a typical method for forming a W plug, tungsten hexa-fluoride (WF₆), silane (SiH₄), and hydrogen (H₂) are injected onto an insulating layer formed with a via hole. Accordingly, a W layer having a thickness of from about 450 Å to about 500 Å is deposited.

When a W layer is deposited to fill a via hole, the W layer can serve as a core layer or a seed layer, and is thinly formed on the surface of the insulating layer and in the via hole.

Next, gas used for the W seed layer is typically removed from a chamber, and the WF₆ and H₂ are injected such that the via hole is filled with the W layer.

FIG. 1 is a cross-sectional view showing a related art via hole 12 after forming a tungsten seed layer 20, and FIG. 2 is a schematic view showing a related art connection between upper and lower metal structures after the via hole 12 of FIG. 1 is formed.

Referring to FIG. 1, when the tungsten seed layer 20 is formed, a large quantity of WF₆ can be provided into the chamber, leading to a difference in partial pressure between the outside and the inside of the via hole 12. This can cause a sloping profile of the seed layer 20 in the via hole 12, such that a thickness of the seed layer 20 on a sidewall of the via hole 12 near the top of the via hole 12 is larger than a thickness of the seed layer 20 on a sidewall near the bottom of the via hole 12.

As can be seen in FIG. 1, a related art process can give a tungsten seed layer 20 with a sloping shape along an internal sidewall surface of the via hole 12.

Since step coverage in the via hole 12 may be poor, and the entrance of the via hole 12 is narrowed near the top of the via hole 12, the tungsten layer 20 may not be completely filled in the via hole 12. Referring to FIG. 2, this can lead to a void 30 formed in the via hole when the tungsten layer is deposited to fill the via hole 12.

Thus, passages for electron movement can be narrowed due to the voids 30, leading to sudden increase in resistance and difficulty in obtaining uniform resistance in each via hole.

Furthermore, the characteristics of the semiconductor device may be changed, the operational reliability of the semiconductor device may be degraded, and the product yield may be decreased.

Accordingly, there exists a need in the art for an improved method of forming a tungsten plug during fabrication of a semiconductor device.

### BRIEF SUMMARY

Embodiments of the present invention provide methods for forming a tungsten plug. Methods of the present invention can be capable of sufficiently filling a tungsten layer by inhibiting voids from being formed in a via hole.

In an embodiment, a method for forming a tungsten plug can comprise: forming a first tungsten seed layer on an insulating layer having a via hole, forming a second tungsten seed layer on the first tungsten seed layer, and forming a tungsten-buried layer in the via hole.

### BRIEF DESCRIPTION OF THE DRAWINGS

FIG. 1 is a cross-sectional view showing a via hole and a tungsten seed layer formed according to a related art process.

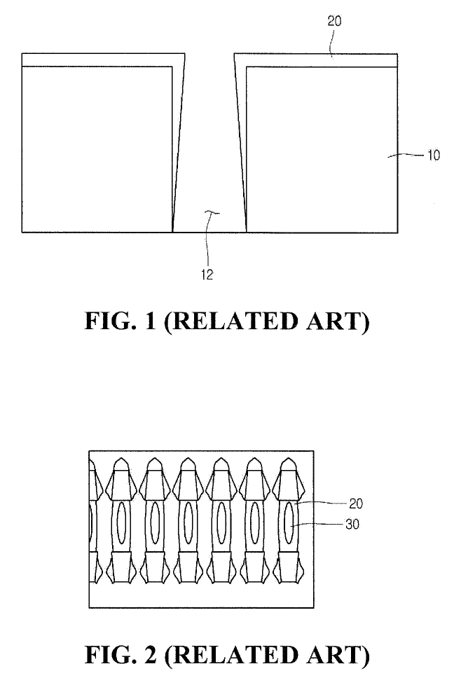

FIG. 2 is a schematic view showing the connection between upper and lower metal structures after a via hole is formed according to a related art process.

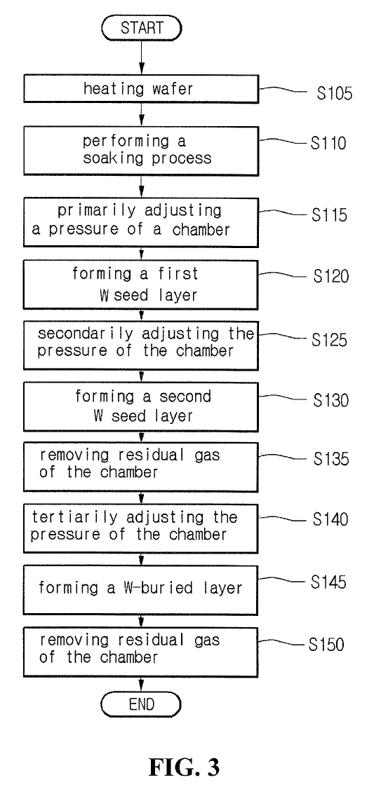

FIG. 3 is a flowchart showing a method for forming a tungsten plug according to an embodiment of the present invention.

FIGS. 4-7 are cross-sectional views showing a method for forming a tungsten plug according to an embodiment of the present invention.

FIG. 8 is a view schematically showing the connection between upper and lower metal structures after a tungsten plug is formed according to an embodiment of the present invention.

### DETAILED DESCRIPTION

Hereinafter, methods for forming a tungsten plug according to embodiments of the present invention will be described in detail with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

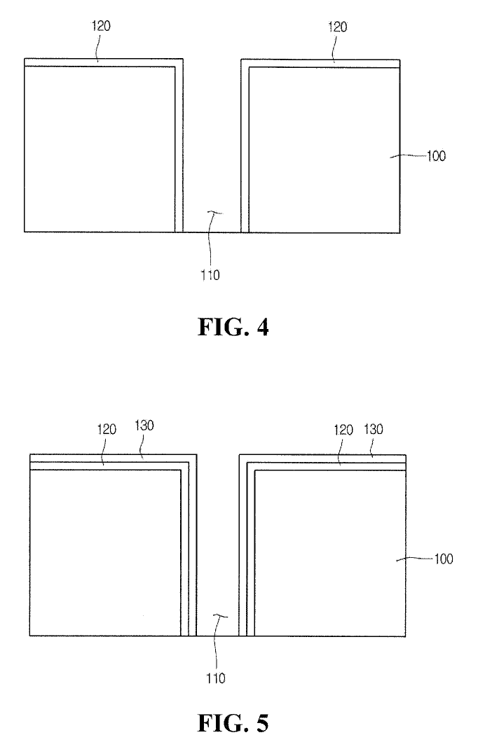

FIG. 3 is a flowchart showing a method for forming a tungsten plug according to an embodiment of the present invention.

Referring to FIG. 3, a wafer can be installed in a chamber of a deposition apparatus, and the wafer can be heated by using a heating device (step S105).

In an embodiment, the wafer can include a semiconductor device layer, a lower metal layer, and an insulating layer having a via hole. The via hole can be used to form a tungsten plug.

Then, silane (SiH₄) can be injected into the chamber, thereby performing a soaking process with respect to the wafer (step S110), and a pressure of the chamber can be primarily adjusted (step S115).

After the pressure of the chamber is primarily adjusted, tungsten hexa-fluoride (WF₆) and SiH₄ can be injected into the chamber at flow rates of about 10 sccm and about 15 sccm, respectively. Hydrogen (H₂) can be injected into the chamber at a flow rate of from about 500 sccm to about 1000 sccm. Accordingly, a first tungsten seed layer can be formed (step S120).

After the first tungsten seed layer is formed, the pressure of the chamber can be secondarily adjusted (step S125).

After the pressure of the chamber is secondarily adjusted, WF₆ can be injected into the chamber at a flow rate of from about 40 sccm to about 60 sccm. Then, H₂ can be injected into the chamber at a flow rate of from about 500 sccm to about 1000 sccm, thereby forming a second tungsten seed layer (step S130).

Next, a purge and pumping process can be performed, so that residues such as remaining WF₆, SiH₄, and H₂ can be removed from the chamber (step S135). The pressure of the chamber can then be tertiarily adjusted (step S140).

After the pressure of the chamber is tertiarily adjusted, WF₆ can be injected into the chamber at a flow rate of from about 90 sccm to about 120 sccm, and H₂ can be injected into the chamber at a flow rate of from about 450 sccm to about 550 sccm. Thus, a tungsten-buried layer can be formed by filling tungsten (step S145).

Thereafter, another purge and pumping process can be performed so that residual gas can be removed from the chamber (step S150).

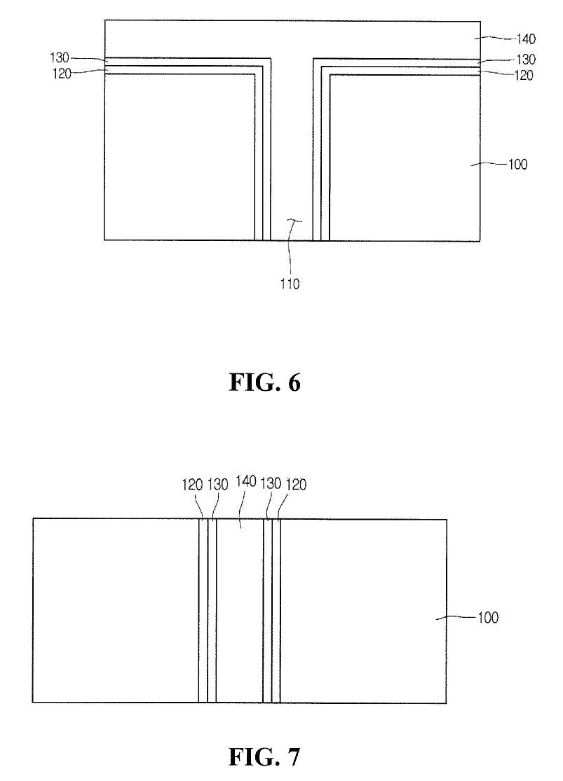

FIGS. 4-7 are cross-sectional views showing a method for forming a tungsten plug according to an embodiment of the present invention.

Referring to FIG. 4, a first tungsten seed layer 120 can be formed on an insulating layer 100 and an internal surface of a via hole 110.

In an embodiment, the first tungsten seed layer 120 can be much thinner than a conventional single tungsten seed layer. That is, less WF₆ can be injected compared to a related art process, so that a partial pressure of gas injected into the via hole 110 can be the same as or approximately the same as a partial pressure of gas injected into the outside of the via hole 110. Accordingly, the first tungsten seed layer 120 can be thinly formed on the internal surface of the via hole 110 and can have an approximately uniform thickness.

Thus, since the first tungsten seed layer 120 can be thin and approximately uniform in thickness, narrowing of the entrance of the via hole 110 by the tungsten seed layer 120 can be inhibited, and reaction gas can penetrate more easily into the via hole 110 in subsequent processes.

Referring again to FIG. 3, after forming the first tungsten seed layer 120, the pressure of the chamber can be secondarily adjusted (step S125).

Then, WF₆ can be injected into the chamber at a flow rate of from about 40 sccm to about 60 sccm. Also, H₂ can be injected into the chamber at a flow rate of from about 500 sccm to about 1000 sccm, thereby forming a second tungsten seed layer (step S130).

Referring to FIG. 5, the second tungsten seed layer 130 can be formed on the first tungsten seed layer 120 on the insulating layer 10 and an internal surface of the via hole 110. In an embodiment, the second tungsten seed layer 130 can have a thickness that is about 1.3 times to about 2.5 times larger than a thickness of the first tungsten seed layer 120.

For example, when the first seed layer 120 is formed with a thickness of from about 100 Å to about 150 Å, the second tungsten seed layer 130 can be formed with a thickness of from about 200 Å to about 250 Å.

Thus, a partial pressure of the WF₆ can be higher in the formation of the second tungsten seed layer 130 than in the formation of the first tungsten seed layer 120. Also, step coverage in the via hole 110 can be improved due to the second tungsten seed layer 130.

According to embodiments, in contrast with a related art process, since the first tungsten seed layer 120 and the second tungsten seed layer 130 can be formed through two processes, the first tungsten seed layer 120 and the second tungsten seed layer can be formed more uniformly on the internal surface of the via hole 110.

In addition, it is possible to inhibit narrowing of the entrance of the via hole 110.

Additionally, according to embodiments, since the first tungsten seed layer 120 and the second tungsten seed layer 130 can be formed through two processes and can be formed with a thickness that is less than that of a conventional single seed layer, a tungsten fill degree can be improved in a subsequent via fill process.

Referring again to FIG. 3, a purge and pumping process can be performed, so that residues such as remaining WF₆, SiH₄, and H₂ can be removed from the chamber (step S135). The pressure of the chamber can be tertiarily adjusted (step S140).

After the pressure of the chamber is tertiarily adjusted, WF₆ can be injected into the chamber at a flow rate of from about 90 sccm to about 120 sccm, and H₂ can be injected into the chamber at a flow rate of about 500 sccm. A tungsten-buried layer can be formed by filling tungsten (step S145).

In an embodiment, the pressure of the chamber when the second tungsten seed layer is formed (i.e., the pressure of the chamber which is secondarily adjusted) can be from about 1 to about 2.5 times larger than the pressure of the chamber when the first tungsten seed layer is formed (i.e., the pressure of the chamber which is primarily adjusted). Additionally, the pressure of the chamber when the tungsten-buried layer is formed (i.e., the pressure of the chamber which is tertiarily adjusted) can be from about 2.5 to about 4.5 times larger than the pressure of the chamber when the first tungsten seed layer is formed (i.e., the pressure of the chamber which is primarily adjusted).

Referring to FIG. 6, the tungsten-buried layer 140 can be filled in the via hole 110 having the second tungsten seed layer 130, and can be formed on the second tungsten seed layer 130 over the insulating layer 100.

Referring again to FIG. 3, a purge and pumping process can be performed to remove residual gas from the chamber (step S150).

Referring to FIG. 7, the first tungsten seed layer 120, the second tungsten seed layer 130, and the tungsten-buried layer 140 on the outside of the via hole 110 (that is, on the surface of the insulating layer 100) can be planarized, thereby forming a tungsten plug. In an embodiment, the first tungsten seed layer 120, the second tungsten seed layer 130, and the tungsten-buried layer 140 can be planarized through a chemical mechanical polishing (CMP) process.

Though not shown, a skilled artisan will recognize that additional structures can be formed on the tungsten plug. For example, a structure including an upper metal interconnection layer, an electrode layer, and a semiconductor device layer can be formed on the tungsten plug.

According to embodiments of the present invention, since the first tungsten seed layer 120 and the second tungsten seed layer 130 can be formed through two processes and can be formed with a thickness that is less than that of a conventional single seed layer, it is possible to improve step coverage in the via hole 110 and inhibit narrowing of the entrance of the via hole 110.

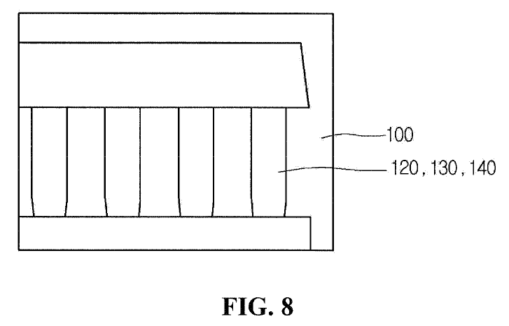

FIG. 8 is a view schematically showing the connection between upper and lower metal structures after a tungsten pug is formed according to an embodiment of the present invention.

Referring to FIG. 8, the fill degree of the tungsten plug can be improved, and the formation of voids can be inhibited.

According to embodiments of the present invention, the formation of voids in a via hole can be inhibited, and a tungsten fill degree of the via hole can be improved.

Additionally, the resistance of the tungsten plug can be minimized, and an approximately uniform resistance can be realized for via holes having approximately the same size.

Moreover, variation of the characteristics of a semiconductor device can be minimized, and the operational reliability of the semiconductor device can be improved. In addition, product yield can be increased.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for forming a tungsten plug, comprising:
forming a first tungsten seed layer on an insulating layer having a via hole, wherein the first tungsten seed layer is formed on a sidewall of the via hole;
forming a second tungsten seed layer on the first tungsten seed layer, the second tungsten seed layer being thicker than the first tungsten seed layer; and
forming a tungsten-buried layer in the via hole.

2. The method according to claim 1, wherein the second tungsten seed layer has a thickness that is from 1.3 times to about 2.5 times larger than a thickness of the first tungsten seed layer.

3. The method according to claim 2, wherein the thickness of the first tungsten seed layer is from about 100 Å to about 150 Å, and wherein the thickness of the second tungsten seed layer is from about 200 Å to about 250 Å.

4. The method according to claim 1, further comprising:
heating a wafer provided with the insulating layer; and
primarily adjusting a pressure of a chamber, before forming the first tungsten seed layer.

5. The method according to claim 4, further comprising injecting silane (SiH₄) into the chamber, after heating the wafer.

6. The method according to claim 4, wherein forming the first tungsten seed layer comprises injecting tungsten hexa-fluoride (WF₆ ) and silane (SiH₄) into the chamber at flow rates of about 10 sccm and about 15 sccm, respectively.

7. The method according to claim 6, wherein forming the first tungsten seed layer further comprises injecting hydrogen (H₂) into the chamber at a flow rate of from about 500 sccm to about 1000 sccm.

8. The method according to claim 4, wherein forming the second tungsten seed layer comprises secondarily adjusting the pressure of the chamber after the first tungsten seed layer is formed.

9. The method according to claim 8, wherein forming the second tungsten seed layer further comprises injecting tungsten hexa-fluoride (WF₆) into the chamber at a flow rate of from about 40 sccm to about 60 sccm.

10. The method according to claim 9, wherein forming the second tungsten seed layer further comprises injecting hydrogen (H₂) into the chamber at a flow rate of from about 500 sccm to about 1000 sccm.

11. The method according to claim 8, wherein forming the tungsten-buried layer comprises:
removing residues in the chamber by performing a purge and pumping process; and
tertiarily adjusting the pressure of the chamber, after forming the second tungsten seed layer.

12. The method according to claim 11, wherein forming the tungsten-buried layer further comprises:
injecting tungsten hexa-fluoride (WF₆) into the chamber at a flow rate of from about 90 sccm to about 120 sccm; and
injecting hydrogen (H₂) into the chamber at a flow rate of from about 450 sccm to about 550 sccm.

13. The method according to claim 11, further comprising planarizing the first tungsten seed layer, the second tungsten seed layer, and the tungsten-buried layer formed outside of the via hole.

14. The method according to claim 13, wherein the second tungsten seed layer has a thickness that is from 1.3 times to about 2.5 times larger than a thickness of the first tungsten seed layer.

15. The method according to claim 1, wherein forming the first tungsten seed layer comprises forming the first tungsten seed layer in a chamber at a first pressure; and wherein the second tungsten seed layer is formed in the chamber at a second pressure that is from about 1 to about 2.5 times larger than the first pressure; and wherein the tungsten-buried layer is formed in the chamber at a third pressure that is from about 2.5 to about 4.5 times larger than the first pressure.

16. The method according to claim 1, further comprising planarizing the first tungsten seed layer, the second tungsten seed layer, and the tungsten-buried layer formed outside of the via hole.

17. The method according to claim 1, wherein forming the second tungsten seed layer comprises secondarily adjusting a pressure of a chamber after the first tungsten seed layer is formed.

18. The method according to claim 1, wherein forming the second tungsten seed layer comprises injecting tungsten hexa-fluoride (WF₆) into a chamber at a flow rate of from about 40 sccm to about 60 sccm.

19. The method according to claim 1, wherein forming the tungsten-buried layer comprises:
removing residues in a chamber by performing a purge and pumping process; and
tertiarily adjusting a pressure of the chamber, after forming the second tungsten seed layer.

20. The method according to claim 1, wherein forming the tungsten-buried layer comprises:
injecting tungsten hexa-fluoride (WF₆) into a chamber at a flow rate of from about 90 sccm to about 120 sccm; and
injecting hydrogen (H₂) into the chamber at a flow rate of from about 450 sccm to about 550 sccm.
